(19) United States
(12) Patent Application Publication
(10) Pub. No.: US 2018/0261977 A1
(43) Pub. Date: Sep. 13, 2018

(54) ORBITAL ANGULAR MOMENTUM MICROLASER AND METHOD

(71) Applicant: The Research Foundation for The State University of New York, Buffalo, NY (US)

(72) Inventors: Liang Feng, Amherst, NY (US); Natalia Litchinitser, Williamsville, NY (US)

(21) Appl. No.: 15/920,371

(22) Filed: Mar. 13, 2018

Related U.S. Application Data
(60) Provisional application No. 62/470,520, filed on Mar. 13, 2017.

(51) Int. Cl. H01S 5/10; H01S 5/04; H01S 5/12

(52) U.S. Cl. CPC H01S 5/1075; H01S 5/1218; H01S 5/1228; H01S 5/041

(57) ABSTRACT

The present disclosure describes a microring OAM laser producing an optical vortex beam with an on-demand topological charge and vector polarization states. This is enabled through combined index and gain/loss modulations at an EP, which breaks the mirror symmetry in the lasing generation dynamics and facilitates unidirectional power oscillation.

### CROSS-REFERENCE TO RELATED APPLICATIONS

This application claims priority to U.S. Provisional Application No. 62/470,520, filed on Mar. 13, 2017, now pending, the disclosure of which is incorporated herein by reference.

### STATEMENT REGARDING FEDERALLY SPONSORED RESEARCH

This invention was made with government support under contract no. W911NF-15-1-0152, DE-SC0014485, and DMR1506884 awarded by the US Army Research Office, US Department of Energy and National Science Foundation, respectively. The government has certain rights in the invention.

### FIELD OF THE DISCLOSURE

This disclosure relates to a micro or nano-scale orbital angular momentum microlaser.

### BACKGROUND OF THE DISCLOSURE

Light typically is a stream of linearly polarized photons, traveling in a straight line, and carrying a linear momentum. However, it has been recognized that beyond the linear momentum, circularly polarized light carries angular momentum. The angular momentum associated with the polarization degree of freedom, or spin angular momentum (“SAM”), can take only one of two values, ±h. In addition to the SAM, it has been also demonstrated that a light beam can carry orbital angular momentum (“OAM”). Such beams possess helical phase fronts so that the Poynting vector within the beam is twisted with respect to the principal axis. This fundamental discovery regarding OAM opened a new branch of optical physics, facilitating studies ranging from rotary photon drag, angular uncertainty relationships, and rotational frequency shifts, to spin-orbital coupling. The OAM degree of freedom has enabled technological advances, for example, edge-enhanced microscopy. Moreover, in contrast to the SAM which can take only two values, the OAM is unbounded. OAM beams are thus being considered as potential candidates for encoding information in both quantum and classical systems. The combined use of spin and orbital angular momenta is expected to enable the implementation of entirely new high-speed secure optical communication and quantum teleportation systems in a multidimensional space, satisfying the exponentially growing demand worldwide for network capacity.

To date, most light sources only produce relatively simple light beams with spatially homogeneous polarization and planar wavefront. Generation of the complex OAM beams usually relies on either bulk devices, such as spiral phase plates, spatial light modulators, and computer-generated holograms, or recently-developed planar optical components, including phase modulation-based metasurfaces, q-plates, and silicon resonators. Although the science of the OAM light beams on the micro- and nanoscale is still in its early days, it is likely to advance our knowledge of light interaction with conventional and artificial atoms (e.g., quantum dots) provided that the OAM beam is focused to subwavelength dimensions, facilitating on-chip functionalities for micromanipulation and microfluidics. Nevertheless, it remains a grand challenge to integrate the existing approaches for OAM microlasers on-a-chip. For an ultimate miniaturized optical communication platform, there is a necessity of independent micro- and nanoscale laser sources emitting complex vector beams carrying the OAM information.

One approach to creating an OAM laser is based on combining a conventional bulk laser with additional phase-front shaping components. Despite being straightforward, this approach relies on rather different device technologies and material platforms, and therefore it is not easily scalable and integratable. Accordingly, there remains a need for an active, semiconductor OAM laser source operable at the micro- or nano-levels.

### BRIEF SUMMARY OF THE DISCLOSURE

In an embodiment, the present disclosure provides a device for emitting a laser beam having orbital angular momentum. The device has a microring resonator made from a gain medium and has a top surface, a bottom surface opposite the top surface, and an outer sidewall. In some embodiments, the substrate is made from indium phosphide (InP) and the microring resonator is made from indium gallium arsenide phosphide (InGaAsP). The outer sidewall is modulated for outcoupling the laser beam. For example, the outer sidewall modulation may be configured to outcouple a laser beam having phase (φₛ) according to φₛ=2πs(N−M)/M, where the location of M equidistant scatters is given by θₛ=2πs where s∈[0, M−1), and N denotes the azimuthal number of a targeted whisper gallery mode.

A refractive index grating is disposed on the top surface of the microring resonator. The grating is configured such that the microring resonator has a refractive index which periodically alternates along the azimuth direction (θ) to include a real component (n′) and an imaginary component (n″) to form an exceptional point where n′=n″. For example, the grating may be configured such that the refractive index is n′ for

$$2 π p / N < θ < 2 π ( p + \frac{1}{4} ) / N and {n}^{″} for 2 π ( p + \frac{3}{8} ) / N < θ < 2 π ( p + \frac{5}{8} ) / N ,$$

where N denotes the azimuthal number of a targeted whisper gallery mode and p takes integer values from the set {0, N−1}. In some embodiments, the grating comprises single-layer Germanium (Ge) structures where the refractive index is n′ and bilayer Chromium/Germanium (Cr/Ge) structures where the refractive index is n″.

In some embodiments, a pump laser is provided. The pump laser can be configured to emit a pump beam incident on the bottom surface of the microring resonator. In some embodiments, the device further includes a substrate and the microring resonator is disposed on a first surface of the substrate.

In another aspect, a method of producing an orbital angular momentum (“OAM”) laser emission is provided. The method includes creating a first whisper-gallery mode (“WGM”) and a second WGM in a microring resonator using a pump beam. The first WGM and second WGM are counter-propagating within the resonator. The first WGM is caused to become suppressed by creating an exceptional point. The exceptional point may be created by a refractive index grating disposed on a top surface of the microring resonator, the grating being configured such that the microring resonator has a refractive index which periodically alternates along the azimuth direction (θ) to include a real component (n′) and an imaginary component (n″) to form an exceptional point where n′=n″. For example, the grating can be configured such that the refractive index is n′ for

$$2 π p / N < θ < 2 π ( p + \frac{1}{4} ) / N and {n}^{″} for 2 π ( p + \frac{3}{8} ) / N < θ < 2 π ( p + \frac{5}{8} ) / N ,$$

where N denotes the azimuthal number of a targeted whisper gallery mode and p takes integer values from the set {0, N−1}.

The method further includes outcoupling the second WGM as an OAM laser using modulations of an outer sidewall of the microring resonator. In some embodiments, the outer sidewall modulation is configured to outcouple a laser beam having phase (φₛ) according to φₛ=2πs(N−M)/M, where the location of M equidistant scatters is given by θₛ=2πs where s∈{0, M−1}.

### DESCRIPTION OF THE DRAWINGS

For a fuller understanding of the nature and objects of the disclosure, reference should be made to the following detailed description taken in conjunction with the accompanying drawings, in which:

FIG. 1A is a schematic of the OAM microlaser according to an embodiment of the present disclosure;

FIG. 1B is spiral phase map showing the simulated phase distribution of emitted light of the OAM microlaser of FIG. 1A;

FIG. 2 is a schematic of a microlaser according to an embodiment of the present disclosure, wherein only a portion of the grating is depicted and the outer sidewall modulations are not shown;

FIG. 3A is a scanning electron microscope image of a microring resonator of an OAM microlaser;

FIG. 3B is a close-up of top surface of the microring of FIG. 3A showing alternating Cr/Ge bilayer and Ge single-layer structures periodically arranged in the azimuthal direction;

FIG. 4 is a chart showing a method according to another embodiment of the present disclosure;

FIG. 5A is a series of three graphs showing laser output as a function of wavelength generated from the techniques of broadband photoluminescence (top), amplified spontaneous emission (middle), and lasing (bottom);

FIG. 5B is a graph showing laser output as a function of peak pump intensity and demonstrating a lasing threshold of approximately 1.0 GW(m⁻²);

FIG. 5C shows the far-field intensity distribution of the laser emission exhibiting a doughnut-shaped profile, where the central dark core is due to the phase singularity at the center of the OAM vertex radiation;

FIG. 5D shows the intensity distribution of the interference patterns between helical and quasilinear phase fronts resulting in two inverted forks (marked with arrows);

FIG. 6A shows the intensity distribution of OAM lasing radiation passing through a zero degree linear polarizer;

FIG. 6B shows the intensity distribution of OAM lasing radiation passing through a 90 degree linear polarizer;

FIG. 6C shows the intensity distribution of OAM lasing radiation passing through a 45 degree linear polarizer; and

FIG. 6D shows the intensity distribution of OAM lasing radiation passing through −45 degree linear polarizer.

### DETAILED DESCRIPTION OF THE DISCLOSURE

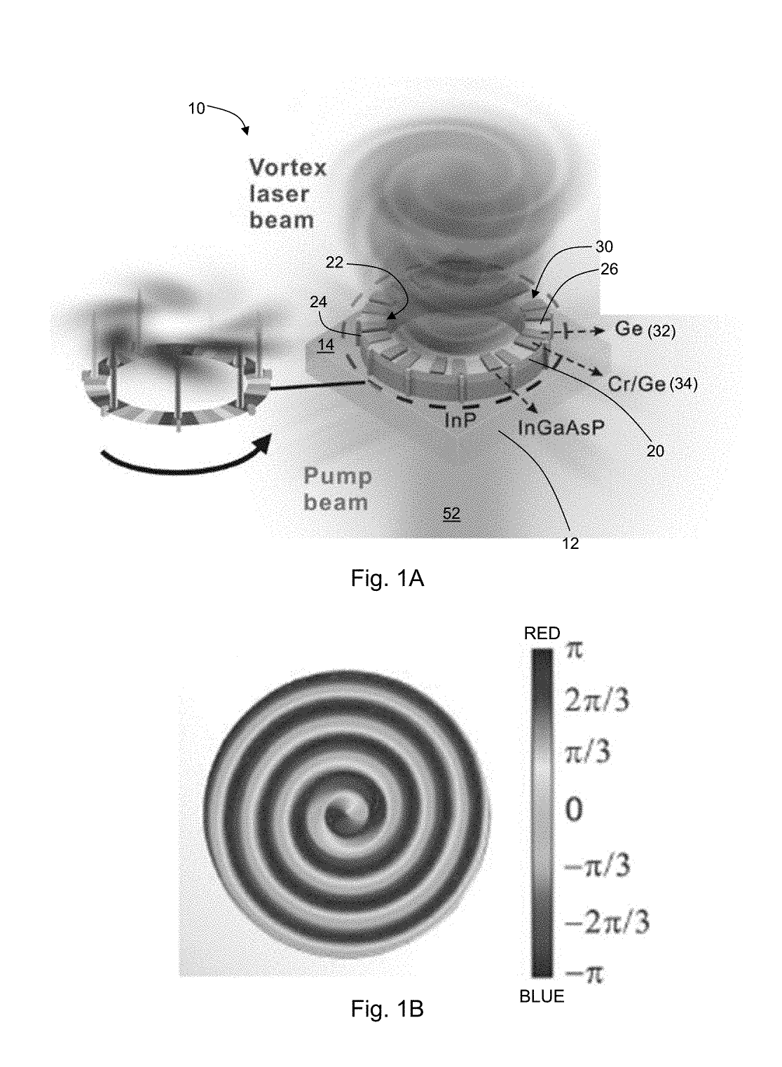

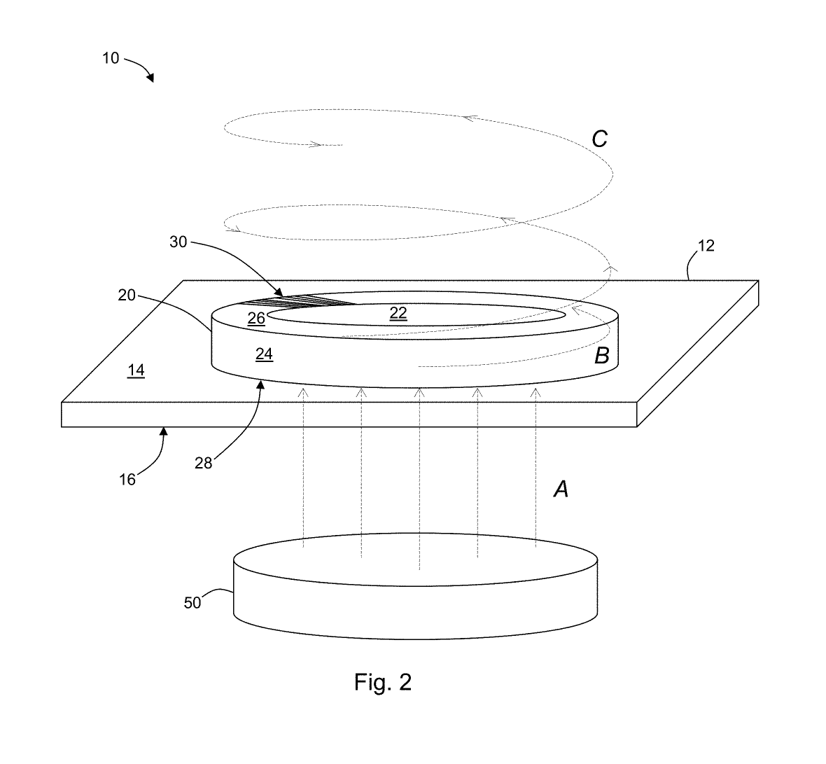

With reference to FIGS. 1A and 2, the present disclosure may be embodied as a device 10 (a “microlaser”) for emitting a laser beam having orbital angular momentum (“OAM”). The device 10 has a microring resonator 20 made of a gain medium. For example, microring resonator 20 may be made from, for example, indium gallium arsenide phosphide (InGaAsP), indium gallium arsenide (InGaAs), aluminum gallium arsenide (AlGaAs), or strained germanium (Ge). In some embodiments, the device 10 includes a substrate 12, and the microring resonator 20 is disposed on a first surface 14 of the substrate 12. The substrate 12 may be made from, for example, indium phosphide (InP).

The microring resonator 20 has a top surface 26, a bottom surface 28 opposite the top surface 26, an inner sidewall 22, an outer sidewall 24, and a top surface 26. The outer sidewall 24 is modulated for outcoupling the emitted laser beam when the microlaser 10 is in use. For example, the modulation of the outer sidewall 24 may be configured with M equidistant scatters located around the microring resonator in the azimuth direction (θ) according to θₛ=2πs where s∈{0, M−1}, such that the emitted laser beam has a phase φₛ according to φₛ=2πs(N−M)/M, where N is the azimuthal number of a targeted whisper gallery mode (“WGM”). Further detail is given below under the heading “Discussion.” In some embodiments, the microring resonator 20 has a height (a distance from bottom surface 28 to top surface 26) of between 100 nm and 2 μm. In some embodiments, the diameter of the microring resonator 20 (measured at the outer sidewall 24) is between 1 μm and 50 μm. In some embodiments, the microring resonator 20 has a wall thickness (sometimes referred to herein as width—measured between the inner sidewall 22 and the outer sidewall 24) of between 300 nm and 1.5 μm. These physical parameters are exemplary and other embodiments may have dimensions that are smaller or larger than these.

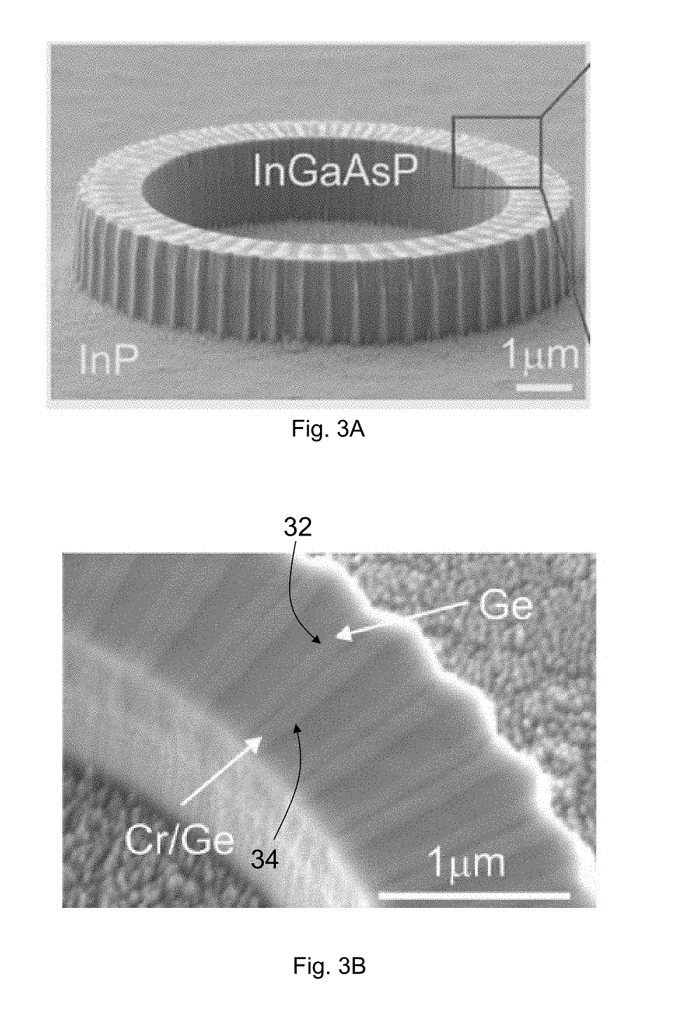

A complex refractive index grating 30 is disposed on the top surface 26 of the microring resonator 20. The grating 30 is configured such that the microring resonator 20 has a refractive index n that is periodically modified to n′ and n″ along the azimuth direction θ to form an exceptional point EP. For example, the grating 30 may comprise single-layer Germanium (Ge) structures 32 where the refractive index is modified to n′, and bilayer Chromium/Germanium (Cr/Ge) structures 34 where the refractive index is modified to n″ (see also FIGS. 3A and 3B). The grating 30 may be configured such that the modulation of refractive index is n′ for

$$2 π p / N < θ < 2 π ( p + \frac{1}{4} ) / N and {n}^{″} for 2 π ( p + \frac{3}{8} ) / N < θ < 2 π ( p + \frac{5}{8} ) / N ,$$

where p takes integer values from the set {0, N−1}. Further description of the grating is provided below.

A device 10 of the present disclosure may be tuned to a wavelengths ranging from, for example, 400-700 nm and 1300-1500 nm, depending on the configuration and materials used.

The microlaser 10 may further comprise a pump laser 50 configured to emit a pump beam A. The pump beam A is directed to the bottom surface 28 of the microring resonator 20. In embodiments having a substrate 12, the pump beam A is directed to a second surface 16 of the substrate 12 such that the pump beam A is transmitted to the microring resonator 20 through the substrate 12.

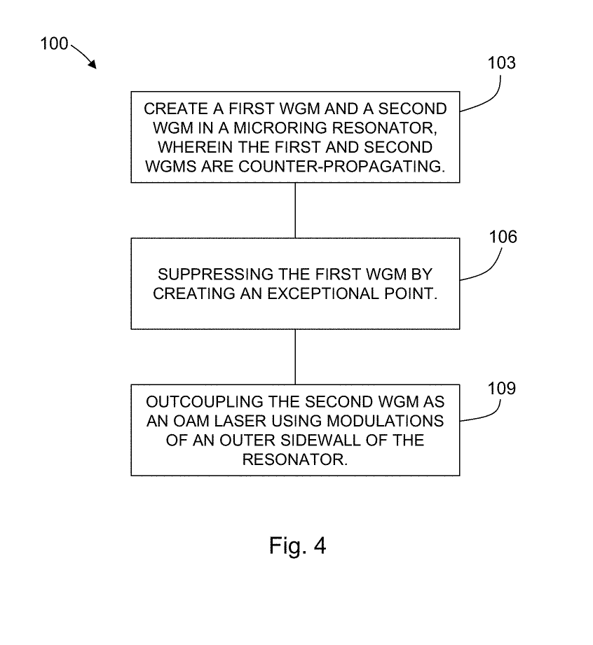

The disclosure may be embodied as a method 100 of producing an orbital angular momentum (“OAM”) laser emission (see, e.g., FIG. 4). The method 100 includes creating 103 a first whisper-gallery mode (“WGM”) and a second WGM in a microring resonator using a pump beam (see FIG. 2, pump beam indicated as A), wherein the first WGM and second WGM are counter-propagating. The first WGM is caused 106 to become suppressed by creating an exceptional point. In this way, the second WGM remains propagating in the microring resonator as a unilateral WGM (FIG. 2, second WGM indicated as B). As further detailed below, the exceptional point may be created by a refractive index grating disposed on a top surface of the microring resonator, the grating being configured such that the microring resonator has a refractive index which periodically alternates along the azimuth direction (θ) to include a real component (n′) and an imaginary component (n″) to form an exceptional point where n′=n″. More particularly, the grating may be configured such that the refractive index is n′ for

$$2 π p / N < θ < 2 π ( p + \frac{1}{4} ) / N and {n}^{″} for 2 π ( p + \frac{3}{8} ) / N < θ < 2 π ( p + \frac{5}{8} ) / N ,$$

where N denotes the azimuthal number of a targeted whisper gallery mode and p takes integer values from the set {0, N−1}.

The second WGM is outcoupled 109 as an OAM laser using modulations of an outer sidewall of the microring resonator. For example, the outer sidewall modulation may be configured to outcouple a laser beam having phase (φₛ) according to φₛ=2s(N−M)/M, where the location of M equidistant scatters is given by θₛ=2πs where s∈{0, M−1}.

In an exemplary embodiment of the presently-disclosed microlaser, a microring resonator was fabricated on an InP substrate. The microring resonator had a diameter of 9 μm, a width of 1.1 μm. The resonator had a 500 nm thick layer of InGaAsP placed on a 1 μm thick layer of InP, for a total height of 1.5 μm. Single-layer Ge structures (13 nm thick) and bilayer Cr/Ge structures (5 nm Cr, 11 nm Ge) are periodically arranged in the azimuthal direction on top of the microring resonator, mimicking real index n′ and gain/loss n″ parts of an EP modulation at n′=n″=0.01 to support unidirectional power circulation. The designed azimuthal order was N=56 at the resonant wavelength of 1472 nm. Equidistant outer sidewall scatters with a total number of M=57 coupled the lasing emissions upward, creating an OAM vortex emission with a helical wavefront. The wavefront had a topological charge defined by i=N−M=1. It should be noted that the microring can be manufactured using different methods. For example, in the above embodiment, the microring was fabricated on an InP substrate. For techniques such as, for example, wafer bonding, the microring can be transferred onto another substrate.

Further detail of the above embodiments and a description of the function is provided below.

### Discussion

In embodiments of the present disclosure, the advantages of semiconductor microlasers are integrated with the pronounced changes in light propagation at the exceptional point (“EP”) to realize a fundamentally new, compact, active orbital angular momentum (“OAM”) source on a complementary metal-oxide-semiconductor (“CMOS”) compatible platform. A microring cavity that supports whispering gallery modes (“WGMs”) is utilized. These modes circulate inside the cavity and carry large OAM. However, because of the mirror symmetry of a ring cavity, clockwise and counterclockwise eigen-WGMs can be simultaneously excited, and their carried OAMs consequently cancel each other. This is evidenced by the quantized phase, taking values of either 0 or π, azimuthally distributed in the ring, which results from the interference between two counter-propagating WGMs. To observe the OAM of an individual WGM, a mechanism of robust selection of either clockwise or counterclockwise mode is introduced. In conventional bulk optics, unidirectional ring lasers have been demonstrated by implementing a nonreciprocal isolator in the light path. The optical isolator breaks the reciprocity between counter-propagating waves, facilitating the desired unidirectional flow. This approach, however, is not feasible at the micro- and nanoscale, as the realization of micrometer-sized isolators is extremely challenging.

To overcome this fundamental limitation, unidirectional power circulation is realized by introducing complex refractive-index modulations to form an EP (FIG. 1A). Driven by non-Hermiticity (i.e., gain and loss in optics), an EP occurs when multiple eigenstates coalesce into one. In embodiments of the presently-disclosed device, EP operation is used to obtain OAM laser emission. In an exemplary embodiment, a microring laser resonator was designed with 500 nm thick InGaAsP multiple quantum wells on an InP substrate. In a particular embodiment, an InGaAsP microring was constructed using one layer of 12 nm 1.20Q InGaAsP followed by 29 periods of 5 nm 1.59Q InGaAsP and 12 nm 1.20Q InGaAsP. A complex refractive-index grating was achieved by placing on top of InGaAsP along the azimuthal direction (θ) periodically alternate single-layer Ge and bilayer Cr/Ge structures, corresponding to the real component (n′) and imaginary (i) component (gain/loss) (n″) in the cavity, respectively:

$$Δ n = \{ \begin{matrix}{in}^{″} for \frac{2 π p}{N} < θ < \frac{2 π ( p + \frac{1}{4} )}{N} \\ {n}^{′} for \frac{2 π ( p + \frac{3}{8} )}{N} < θ < \frac{2 π ( p + \frac{5}{8} )}{N}\end{matrix} \qquad ( 1 )$$

where N denotes the azimuthal number of the targeted WGM and p takes integer values from the set {0, N−1}. An EP is obtained when the amplitudes of index and gain/loss gratings are set equal (i.e., n′=n″). At EP, the Fourier transform of the complex refractive-index modulation is one-sided, yielding one-way distributed feedback and robust unidirectional laser emission above threshold. As a result, the counterclockwise WGM unidirectionally circulates in the cavity carrying large OAM through the azimuthally continuous phase evolution.

The OAM associated with the unidirectional power flow is extracted upward into free space by introducing sidewall modulations periodically arranged along the microring perimeter. The azimuthal phase dependence of the targeted unidirectional N^{th} WGM is given by φ=Nθ. The sidewall modulations coherently scatter light, with the phase continuously varying in the azimuthal direction, defined by the locations of the scatters (FIG. 1A). For M equidistant scatters, the locations of the scatters are given by θₛ=2πs/M where s ∈{0, M−1}, resulting in the extracted phase θₛ=2πsN/M that carries OAM. Because the physically meaningful phase is measured modulo 2π, one can subtract 2πs from each of the extracted phases and derive:

$${θ}_{s} = \frac{2 π s ( N - M )}{M} \qquad ( 2 )$$

Equation 2 shows that the extracted phase increases linearly from 0 to 2π(N−M), thereby creating a vortex beam with topological charge l=N−M. FIG. 1B shows the modeling result of the vortex laser emission from an exemplary OAM microlaser, where N=56 and M=57. The phase of the electric field changes by 2π upon one full circle around the center of the vortex. The phase is continuous everywhere except for the center of the emission path, presenting a topological phase singularity point at the beam axis. The topological charge of the vortex emission can be viewed as the number of twists done by the wavefront in one wavelength, exhibiting OAM lasing of charge l=−1.

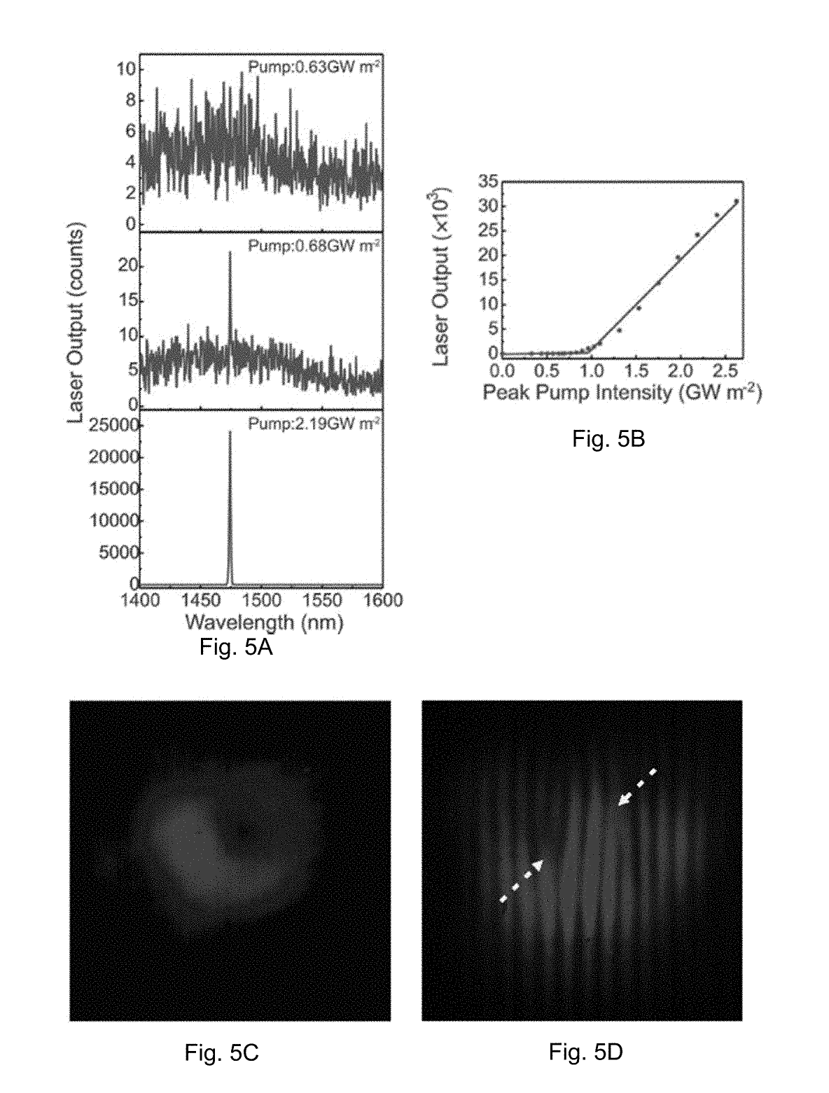

The exemplary OAM microlaser with the EP modulation by periodically arranged Ge and Cr/Ge (FIGS. 3A and 3B) was fabricated by means of overlay electron beam lithography. The unidirectional power flow oscillating in the cavity eliminates the undesired spatial hole-burning effect that would be created by the interference pattern of two counter propagating WGMs. The preferential gain saturation in the antinodes of the interference pattern would cause spatial gain inhomogeneity, leading to a decrease in the laser slope efficiency, multilongitudinal mode operation, and unstable laser emission. In this embodiment of an OAM microlaser, unidirectional power flow forced at the EP modulation enables efficient and stable single-mode lasing with a sideband suppression ratio of ˜40 dB (FIG. 5A). In the transition from broadband photoluminescence (“PL”), to amplified spontaneous emission (“ASE”), and finally to lasing (FIGS. 5A and 5B), the emission peak stabilized at the same resonant wavelength, demonstrating the avoidance of multimode oscillation typically existing in a microring cavity. The OAM characteristics, such as the vortex nature and the phase singularity, were characterized by analyzing the spatial intensity profile of lasing emission and its self-interference. In the far field, the intensity of lasing emission was observed to be spatially distributed in a doughnut shape with a dark core in the center (FIG. 5C). The observed dark center is due to the topological phase singularity at the beam axis where the phase becomes discontinuous, as predicted in FIG. 1B.

The presence of the OAM was validated in the exemplary embodiment by the self-interference of two doughnut-shaped beams split from the same lasing emission. In each doughnut beam, because of its OAM, optical phase varies more markedly with a helical phase front close to the central singularity area, whereas the outer doughnut area is of a relatively uniform quasiplanar phase front. At the observation plane, a horizontal offset was intentionally created between two doughnut beams, so that the dark center of one beam overlapped with the bright doughnut area of the other, and vice versa. The resulting interference patterns between the helical and quasiplanar phase fronts revealed two inverted forks (FIG. 5D), as the quasiplanar and helical phases were reversed at the centers of two doughnuts. For both of them, the single fringe split into two at the fork dislocation, evidently confirming that the radiation from the exemplary OAM laser according to the present disclosure was an optical vortex of topological charge l=−1.

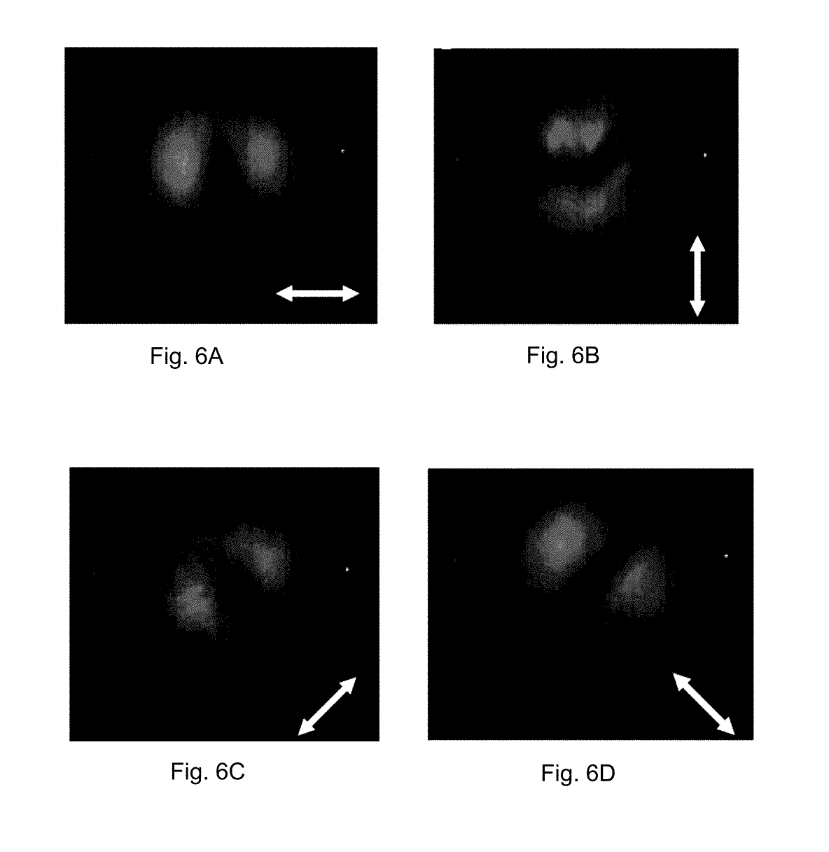

The polarization properties of the demonstrated OAM microlaser can be designed on demand. In particular, radially polarized beams, characterized by a non-uniform spatial distribution of their polarization vector, have enabled unique functionalities, such as high-spatial resolution microscopy by their sharp focusing. Although the conventional schemes require external optical components, such as geometric phase-based diffraction elements, radially polarized beams can be directly produced from the presently-disclosed OAM microlaser. In a microring cavity, the resonant mode can be designed to be either quasi-transverse magnetic (“TM”) or quasi-transverse electric (“TE”). The radially polarized component of the quasi-TM mode is tightly confined at the microring perimeter and sensitive to sidewall modulations, facilitating the outcoupling of this mode from the laser. Therefore, in the microring cavity, the dominant oscillating mode is designed to be a quasi-TM mode, and its scattering by the sidewall modulation results in the radially polarized OAM lasing. In experiments, the polarization state of the OAM lasing was validated. After transmission through a linear polarizer, the doughnut profile splits into two lobes aligned along the orientation of the polarizer (FIGS. 6A-6D). The two lobes remained parallel to the polarization axis regardless of the rotation of the polarizer, manifesting pure radially polarized OAM lasing. Additionally, in contrast to linearly polarized OAM modes that are not compatible with optical fibers, fibers can support radially polarized OAM eigenmodes.

Although the present disclosure has been described with respect to one or more particular embodiments, it will be understood that other embodiments of the present disclosure may be made without departing from the spirit and scope of the present disclosure.

What is claimed is:

1. A device for emitting a laser beam having orbital angular momentum, the device comprising:
a microring resonator made from a gain medium and having a top surface, a bottom surface opposite the top surface, and an outer sidewall, and wherein the outer sidewall is modulated for outcoupling the laser beam; and
a refractive index grating disposed on the top surface of the microring resonator, the grating being configured such that the microring resonator has a refractive index which periodically alternates along the azimuth direction (θ) to include a real component (n′) and an imaginary component (n″) to form an exceptional point where n′=n″.

2. The device of claim 1, wherein the grating is configured such that the refractive index is n′ for
$$2 π p / N < θ < 2 π ( p + \frac{1}{4} ) / N and {n}^{″} for 2 π ( p + \frac{3}{8} ) / N < θ < 2 π ( p + \frac{5}{8} ) / N ,$$
where N denotes the azimuthal number of a targeted whisper gallery mode and p takes integer values from the set {0, N−1}.

3. The device of claim 2, wherein the grating comprises single-layer Germanium (Ge) structures where the refractive index is n′ and bilayer Chromium/Germanium (Cr/Ge) structures where the refractive index is n″.

4. The device of claim 2, wherein the outer sidewall modulation is configured to outcouple a laser beam having phase (φₛ) according to φₛ=2πs(N−M)/M, where the location of M equidistant scatters is given by φₛ=2πs where s ∈{0, M−1}.

5. The device of claim 1, wherein the microring resonator is made from indium gallium arsenide phosphide (InGaAsP), indium gallium arsenide (InGaAs), aluminum gallium arsenide (AlGaAs), or strained germanium (Ge).

6. The device of claim 1, further comprising a pump laser configured to emit a pump beam incident on the bottom surface of the microring resonator.

7. The device of claim 1, further comprising a substrate and wherein the microring resonator is disposed on a first surface of the substrate.

8. A method of producing an orbital angular momentum (“OAM”) laser emission, comprising:
creating a first whisper-gallery mode (“WGM”) and a second WGM in a microring resonator using a pump beam, wherein the first WGM and second WGM are counter-propagating;
causing the first WGM to become suppressed by creating an exceptional point; and
outcoupling the second WGM as an OAM laser using modulations of an outer sidewall of the microring resonator.

9. The method of claim 8, wherein the exceptional point is created by a refractive index grating disposed on a top surface of the microring resonator, the grating being configured such that the microring resonator has a refractive index which periodically alternates along the azimuth direction (θ) to include a real component (n′) and an imaginary component (n″) to form an exceptional point where n′=n″.

10. The method of claim 9, wherein the grating is configured such that the refractive index is n′
$$2 π p / N < θ < 2 π ( p + \frac{1}{4} ) / N and {n}^{″} for 2 π ( p + \frac{3}{8} ) / N < θ < 2 π ( p + \frac{5}{8} ) / N ,$$
where N denotes the azimuthal number of a targeted whisper gallery mode and p takes integer values from the set {0, N−1}.

11. The device of claim 10, wherein the outer sidewall modulation is configured to outcouple a laser beam having phase (φₛ) according to φₛ=2πs(N−M)/M, where the location of M equidistant scatters is given by θₛ=2πs where s ∈{0, M−1}.
